(19) United States
(12) Patent Application Publication
(10) Pub. No.: US 2026/0122951 A1
(43) Pub. Date: Apr. 30, 2026

(54) SEMICONDUCTOR DEVICES WITH COMPOSITE DIELECTRIC LAYERS UNDER FIELD PLATES AND METHODS OF FABRICATION THEREOF

(71) Applicant: TEXAS INSTRUMENTS INCORPORATED, Dallas, TX (US)

(72) Inventors: Dong Seup Lee, Allen, TX (US); Yasumasa Koda, Aizuwakamatsu-Shi Fukushima (JP)

(21) Appl. No.: 18/933,145

(22) Filed: Oct. 31, 2024

(51) Int. Cl. H01L 29/778; H01L 29/20; H01L 29/40; H01L 29/417; H01L 29/66

(52) U.S. Cl. CPC H10D 30/475; H10D 30/015; H10D 62/8503; H10D 64/112; H10D 64/251

(57) ABSTRACT

Semiconductor devices and fabrication methods thereof are described. For example, a semiconductor device includes a semiconductor substrate including a source region, a gate region, a drain region, and a drain access region between the gate region and the drain region. The semiconductor device further includes a heterojunction structure disposed over the semiconductor substrate, the heterojunction structure including a buffer layer over the semiconductor substrate and a barrier layer over the buffer layer. The semiconductor device further includes a field plate disposed over the heterojunction structure and including an edge terminated over the drain access region. The semiconductor device further includes a composite dielectric layer disposed below the field plate, wherein the composite dielectric layer comprises a first dielectric layer having a first dielectric constant and a second dielectric layer having a second dielectric constant different than the first dielectric constant.

### TECHNICAL FIELD

The present disclosure relates to the field of semiconductor devices, and more particularly, but not exclusively, to gallium nitride-based semiconductor devices (GaN devices).

### BACKGROUND

GaN devices can deliver various characteristics that are superior to silicon-based semiconductor devices. GaN devices typically include a heterojunction structure that induces highly-mobile 2-dimensional electron gas (2DEG) at the interface of two dissimilar semiconductor materials. GaN devices have faster switching speeds than silicon-based semiconductor devices, as well as better reverse-recovery performance. GaN devices are suitable for low-loss and high-efficiency performance applications.

### SUMMARY

The present disclosure describes semiconductor devices with composite dielectric layers under field plates and methods of fabrication thereof. This summary is not an extensive overview of the disclosure. Rather, a purpose of the summary is to present some examples of the present disclosure in a simplified form as a prelude to a more detailed description that is presented later.

In one example, a semiconductor device includes semiconductor substrate including a source region, a gate region, a drain region, and a drain access region between the gate region and the drain region. The semiconductor device further includes a heterojunction structure disposed over the semiconductor substrate, the heterojunction structure including a buffer layer over the semiconductor substrate and a barrier layer over the buffer layer. The semiconductor device further includes a field plate disposed over the heterojunction structure and including an edge terminated over the drain access region. The semiconductor device further includes a composite dielectric layer disposed below the field plate, wherein the composite dielectric layer includes a first dielectric layer having a first dielectric constant and a second dielectric layer having a second dielectric constant different than the first dielectric constant.

In another example, a semiconductor device includes a GaN heterojunction structure disposed over a substrate, the GaN heterojunction structure including a barrier layer disposed on a GaN layer. The semiconductor device further includes a source contact, a drain contact, and a gate structure disposed over the GaN heterojunction structure and between the source contact and the drain contact. The gate structure includes a p-doped GaN layer disposed on the barrier layer of the GaN heterojunction structure, and a gate electrode disposed on the p-doped GaN layer. The semiconductor device further includes a set of field plates disposed over the gate structure and extending from the source contact toward the drain contact. The semiconductor device further includes a set of composite dielectric layers, a first one of the set of composite dielectric layers being disposed below a first one of the set of field plates, a second one of the set of composite dielectric layers being disposed below a second one of the set of field plates. Each of the set of composite dielectric layers includes a first dielectric layer having a first dielectric constant and a second dielectric layer having a second dielectric constant different than the first dielectric constant.

In an additional example, a method of fabricating a semiconductor device includes forming a semiconductor substrate including a source region, a gate region, a drain region, and a drain access region between the gate region and the drain region. The method further includes forming a heterojunction structure over the semiconductor substrate, the heterojunction structure including a buffer layer over the semiconductor substrate and a barrier layer over the buffer layer. The method further includes forming a composite dielectric layer over the heterojunction structure, wherein the composite dielectric layer includes a first dielectric layer having a first dielectric constant and a second dielectric layer having a second dielectric constant different than the first dielectric constant. The method further includes forming a field plate over the composite dielectric layer and including an edge terminated over the drain access region.

### BRIEF DESCRIPTION OF THE DRAWINGS

FIGS. 1A-1J are cross-sectional views of a process flow for forming an enhancement-mode type GaN device with composite dielectric layers under field plates in accordance with an example of the present disclosure;

FIG. 2 is a cross-sectional view of an enhancement-mode type GaN device with composite dielectric layers under field plates in accordance with another example of the present disclosure;

FIG. 3 is a cross-sectional view of a depletion-mode type GaN device with composite dielectric layers under field plates in accordance with an example of the present disclosure; and

FIGS. 4A through 4C are respective cross-sectional views of portions of semiconductor devices with composite dielectric layers under a field plate in accordance with other examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

A GaN device (e.g., GaN transistor) may be regarded as a high electron mobility transistor (HEMT) in view of a layer of highly-mobile electrons formed therein referred to as a 2-dimensional electron gas (2DEG) or a 2DEG layer. The 2DEG can be formed at an interface of a heterojunction structure having two dissimilar semiconductor materials in contact with each other. For example, a layer of a group-III nitride-based alloy material (e.g., aluminum gallium nitride (AlGaN)) can be formed (e.g., epitaxially grown) on another layer of a group-III nitride material (e.g., gallium nitride (GaN)) to form a heterojunction structure. Conduction-band offset between the two semiconductor materials and/or polarization discontinuity present in such a heterojunction structure can induce the 2DEG at its interface—e.g., at the surface of the GaN layer in contact with the AlGaN layer.

The phenomenon of inducing/forming the 2DEG at the interface of the heterojunction structure may be modeled as: (i) forming a sheet of fixed positive charges at the interface of the heterojunction structure; and (ii) accumulating electrons at the interface to compensate the positive charges at the interface. Although some of the description herein focuses on heterojunction structures including a GaN-based alloy layer (e.g., AlGaN layer) and a GaN layer for illustration purposes, the present disclosure is not limited thereto. For example, methods described herein can be applied to other heterojunction structures that can induce the 2DEG at their interface.

The 2DEG provides a channel for current conduction between source and drain contacts of the GaN device. As such, the channel between the source and drain contacts may be referred to as a surface channel or a device channel. Moreover, a gate structure is positioned between the source and drain contacts to control the current conduction. A GaN device can be configured as an enhancement-mode GaN device (e-mode GaN device) or a depletion-mode GaN device (d-mode GaN device). The e-mode GaN device is configured to have electrons of the 2DEG depleted (absent) under the gate structure resulting in a normally-OFF device. The e-mode GaN device can then be turned ON by applying a positive voltage to the gate structure—e.g., a threshold voltage. On the other hand, the d-mode GaN device is configured to have the 2DEG present under the gate structure resulting in a normally-ON device. The d-mode GaN device can be turned OFF by applying a negative voltage to the gate structure.

In some examples, the gate structure of an e-mode GaN device includes a p-type doped (p-doped) gallium nitride (p-GaN) layer disposed on the heterojunction structure with a gate electrode disposed on the p-GaN layer. The p-GaN layer serves to deplete the 2DEG beneath the gate structure at a zero or negative gate voltage. Applying a positive gate voltage to the gate electrode enhances the 2DEG under the gate structure and turns the e-mode GaN device ON to allow current flow between the source and drain contacts.

Silicon nitride (SiN) is a dielectric material used in a GaN device for one or more purposes. For example, SiN can provide surface passivation to reduce the chemical reactivity of the surface of the heterojunction structure. However, depending on the deposition process implemented, SiN can contain a significant amount of hydrogen (H), e.g., in the range of 15-25 atomic percent, and thus may be referred to as “hydrogenated” SiN. A problem that has been observed is that H atoms from the SiN layer diffuse into the p-GaN layer of an e-mode GaN device, especially at high-temperature processing conditions. The H atoms may combine with the dopant atoms (e.g., magnesium (Mg)) in the p-GaN layer resulting in the dopant atoms deactivated, rendering the p-GaN layer into a weakly-doped or close-to-intrinsic p-GaN layer—e.g., p-GaN layer deactivation. Then, when applying a positive gate voltage, the p-GaN layer may become fully depleted, decreasing gate capacitance and decreasing the threshold voltage. Such reduction in the gate capacitance and/or the threshold voltage causes the gate structure to lose control over the channel.

One solution for minimizing or eliminating the p-GaN deactivation issue described above is to replace SiN, as the surface passivation material, with an alternative dielectric material having comparatively less hydrogen content than SiN. Examples of such alternative dielectric materials can include silicon oxynitride (SiON) or tetraethoxysilane (TEOS). However, SiON, TEOS, and other dielectric materials with a lower hydrogen content than SiN, also have lower dielectric constants than SiN. For example, SiN can have a dielectric constant (κ) ranging between about 8 to 9, while κ for SiON can range between about 4 to 7, and TEOS between about 4 to 6. The lower dielectric constant, however, can result in an increase in the magnitude of the electric field present in the surface passivation layer, particularly at the interface of the surface passivation layer and an edge of a field plate formed immediately there-above. The increased electric field can lead to a degradation in the time-dependent dielectric breakdown (TDDB) lifetime of the GaN device.

To address the above and other technical challenges in GaN and other heterojunction structure-based semiconductor device designs, examples of the present disclosure describe semiconductor devices with composite dielectric layers disposed under field plates and methods of fabrication thereof.

In one example, a semiconductor device includes a semiconductor substrate including a source region, a gate region, a drain region, and a drain access region between the gate region and the drain region. The semiconductor device further includes a heterojunction structure disposed over the semiconductor substrate, the heterojunction structure including a buffer layer over the semiconductor substrate and a barrier layer over the buffer layer. The semiconductor device further includes a field plate disposed over the heterojunction structure and including an edge terminated over the drain access region. The semiconductor device further includes a composite dielectric layer disposed below the field plate, wherein the composite dielectric layer includes a first dielectric layer having a first dielectric constant and a second dielectric layer having a second dielectric constant different than the first dielectric constant.

In some examples, the first dielectric layer may be disposed between the field plate and the second dielectric layer, the first dielectric layer having a greater dielectric constant than the second dielectric layer. The first dielectric layer may include a silicon nitride-based material or a transition metal oxide-based material, and the second dielectric layer may include a silicon oxide-based material. Also, in some examples, the first dielectric layer may have a first thickness, and the second dielectric layer may have a second thickness greater than the first thickness. The first dielectric layer, in some examples, may terminate at the edge of the field plate and, in other examples, the first dielectric layer may extend beyond the edge of the field plate.

In some examples, the semiconductor device may include a third dielectric layer disposed on the field plate, wherein the third dielectric layer may have a third dielectric constant greater than the second dielectric layer. Still further, in some examples, the third dielectric layer may connect with the first dielectric layer at the edge of the field plate.

Further, in some examples, the semiconductor device may include a set of composite dielectric layers. The composite dielectric layer may be a first one of the set of composite dielectric layers and disposed below the field plate, and a second one of the set of composite dielectric layers may be disposed above the field plate. The second one of the set of composite dielectric layers may include a first dielectric layer having the first dielectric constant and a second dielectric layer having the second dielectric constant.

In some examples, e.g., an e-mode GaN device, the gate region includes a p-doped GaN layer disposed on the barrier layer of the heterojunction structure, and a gate electrode disposed on the p-doped GaN layer.

In some other examples, e.g., a d-mode GaN device, the gate region includes a gate dielectric layer disposed over the barrier layer of the heterojunction structure, and a gate electrode disposed above the barrier layer and partially disposed in the gate dielectric layer.

In another example, a semiconductor device includes a GaN heterojunction structure disposed over a substrate, the GaN heterojunction structure including a barrier layer disposed on a GaN layer. The semiconductor device further includes a source contact, a drain contact, and a gate structure disposed over the GaN heterojunction structure and between the source contact and the drain contact. The gate structure includes a p-doped GaN layer disposed on the barrier layer of the GaN heterojunction structure, and a gate electrode disposed on the p-doped GaN layer. The semiconductor device further includes a set of field plates disposed over the gate structure and extending from the source contact toward the drain contact. The semiconductor device also includes a set of composite dielectric layers, a first one of the set of composite dielectric layers being disposed below a first one of the set of field plates, and a second one of the set of composite dielectric layers being disposed below a second one of the set of field plates. Each of the set of composite dielectric layers includes a first dielectric layer having a first dielectric constant and a second dielectric layer having a second dielectric constant different than the first dielectric constant.

In some examples, the first dielectric layer of each of the set of composite dielectric layers may be disposed between the corresponding field plate and the second dielectric layer, the first dielectric layer having a greater dielectric constant than the second dielectric layer.

In some examples, the first dielectric layer of each of the set of composite dielectric layers may have a hydrogen content greater than the second dielectric layer.

In some examples, the first dielectric layer of each of the set of composite dielectric layers may include a silicon nitride-based material or a transition metal oxide-based material, and the second dielectric layer includes a silicon oxide-based material.

In some other examples, the semiconductor device further may include a third dielectric layer disposed on the lower one of the set of field plates and having the same dielectric constant as the first dielectric layer of each of the set of composite dielectric layers. The third dielectric layer may connect with the first dielectric layer of the composite dielectric layer corresponding to the lower one of the set of field plates.

In an additional example, a method of fabricating a semiconductor device includes forming a semiconductor substrate including a source region, a gate region, a drain region, and a drain access region between the gate region and the drain region. The method further includes forming a heterojunction structure over the semiconductor substrate, the heterojunction structure including a buffer layer over the semiconductor substrate and a barrier layer over the buffer layer. The method further includes forming a composite dielectric layer over the heterojunction structure, wherein the composite dielectric layer includes a first dielectric layer having a first dielectric constant and a second dielectric layer having a second dielectric constant different than the first dielectric constant. The method further includes forming a field plate over the composite dielectric layer and including an edge terminated over the drain access region.

In some examples, the first dielectric layer may be formed between the field plate and the second dielectric layer, the first dielectric layer having a greater dielectric constant than the second dielectric layer, and the first dielectric layer having a first thickness and the second dielectric layer having a second thickness greater than the first thickness.

In some other examples, the method may include forming a third dielectric layer on the field plate, wherein the third dielectric layer has a third dielectric constant greater than the second dielectric layer.

In some examples, the method may include forming a set of composite dielectric layers. The composite dielectric layer may be a first one of the set of composite dielectric layers and formed below the field plate, while a second one of the set of composite dielectric layers is formed above the field plate. The second one of the set of composite dielectric layers including a first dielectric layer having the first dielectric constant and a second dielectric layer having the second dielectric constant.

Further, in some examples, forming the semiconductor substrate may further include forming the gate region to include a p-doped GaN layer on the barrier layer of the heterojunction structure, and a gate electrode on the p-doped GaN layer.

In some other examples, forming the semiconductor substrate may further include forming the gate region to include a gate dielectric layer over the barrier layer of the heterojunction structure, and a gate electrode partially in the gate dielectric layer and above the barrier layer.

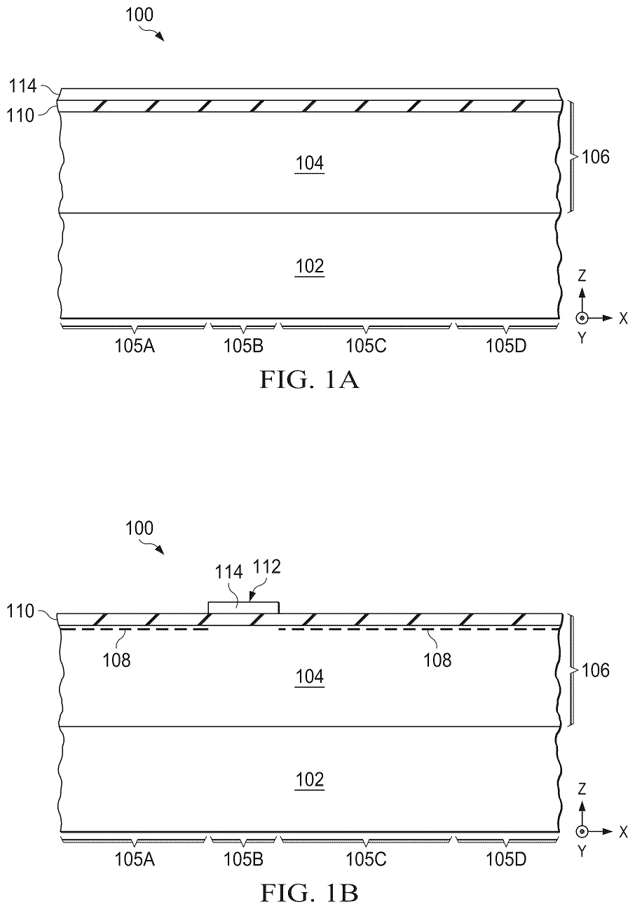

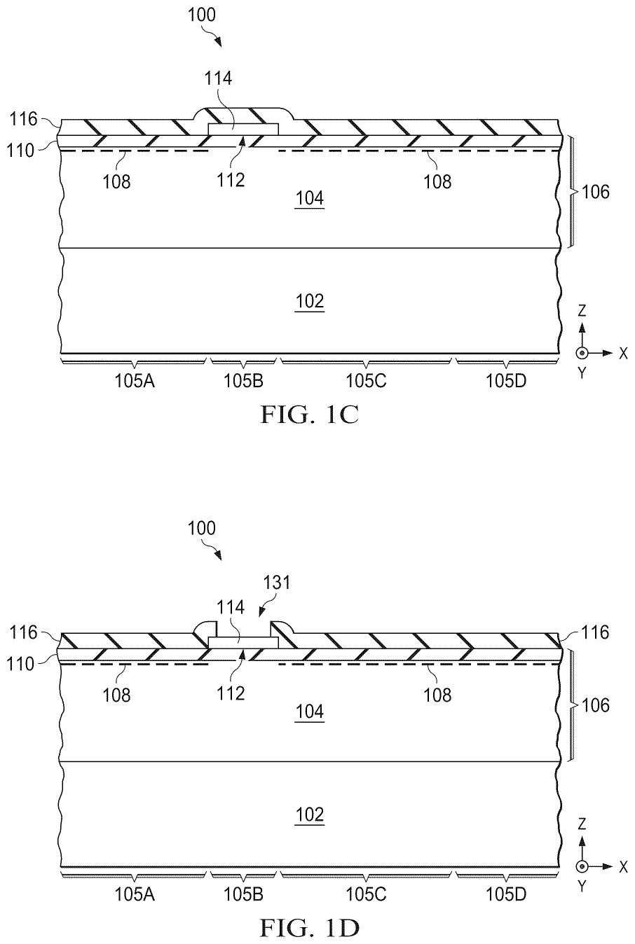

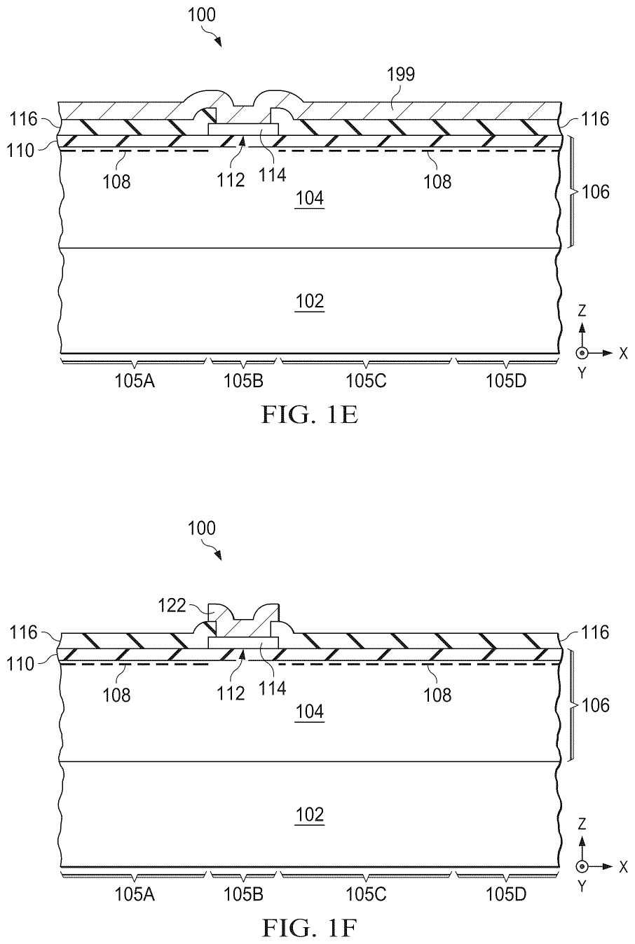

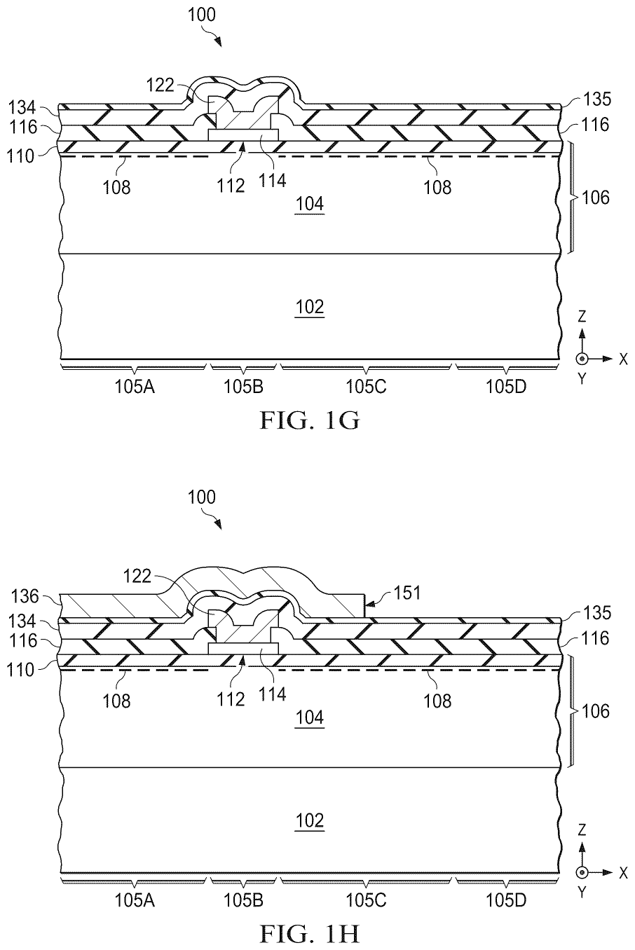

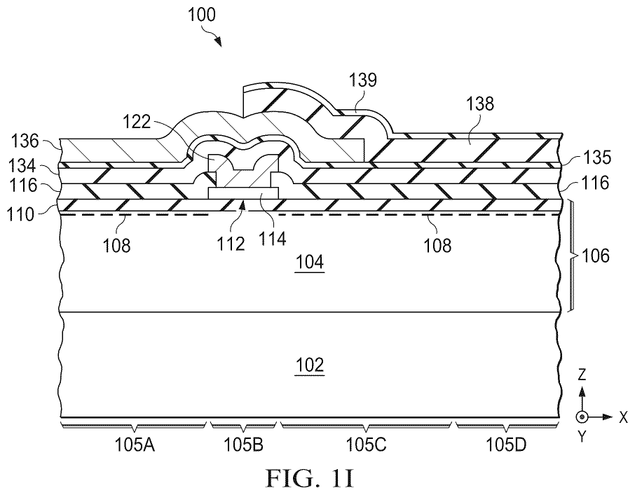

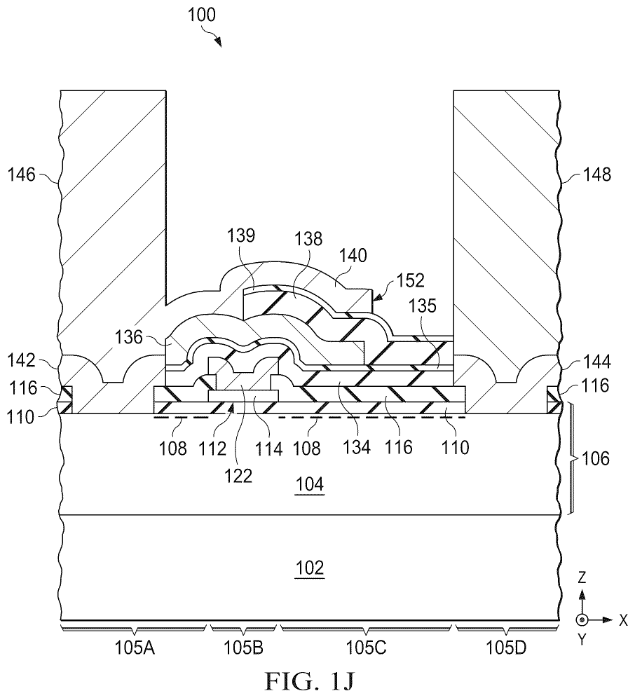

Referring now to FIGS. 1A-1J, cross-sectional views are shown of a process flow for forming an e-mode type GaN device (semiconductor device) 100 with composite dielectric layers under field plates in accordance with an example of the present disclosure. While FIGS. 1A-1J depict a “gate first” process flow (wherein a gate stack (structure) is formed prior to formation of source/drain contacts), in other examples, composite dielectric layers under field plates can be fabricated in accordance with a “gate last” process flow (wherein the gate stack is formed after formation of source/drain contacts).

FIG. 1A depicts an intermediate stage of the GaN device 100 formed on a portion of a semiconductor substrate 102, which may be provided as a silicon wafer, a silicon-on-sapphire wafer, or a silicon carbide wafer, and/or as semiconductor substrates including cores configured for a matching coefficient of thermal expansion (CTE), and/or the like. A buffer layer 104 comprising one or more layers of group-III-N semiconductor material is formed on the semiconductor substrate 102. In some examples where the semiconductor substrate 102 is implemented as a silicon wafer or a sapphire wafer, the buffer layer 104 may include a nucleation layer having a stoichiometry that includes aluminum to match a lattice constant of the semiconductor substrate 102. In some examples, the buffer layer 104 may further include layers/sublayers of aluminum gallium nitride (AlGaN) with decreasing aluminum content, including an unintentionally doped (UID) GaN sublayer in some arrangements. For purposes of examples herein, the various layers/sublayers of a buffer layer, e.g., the buffer layer 104, are not specifically shown in the figures of the present disclosure.

Depending on implementation, the buffer layer 104 may have a thickness of about 1 micron (μm) to several microns, e.g., 3.5 μm to 7.0 μm, which may be formed by a suitable epitaxial process, e.g., a metal organic vapor phase epitaxy (MOVPE) process with several operations to form the various layers and/or sublayers. In some examples, an example buffer layer 104 may include a stack of multiple layers/sublayers of suitable materials and compositions (e.g., GaN, AlGaN) as noted above, where the layers/sublayers may have variable thicknesses depending on the technology and device application. In some examples, the buffer layer 104 may include AlGaN-based transition layers, epitaxial layers with strain-layer superlattice (SLS) structures, and the like.

The buffer layer 104 may be formed over an area of the semiconductor substrate 102, where different regions such as a source region 105A, a gate region 105B, a drain region 105D and a drain access region 105C between the gate region 105B and the drain region 105D may be provided with respect to the GaN device 100. The source region 105A may be regarded as including a source access region (not specifically shown in the figures but similar to the drain access region 105C), which may refer to a region between a source contact (as will be shown in the context of FIG. 1J) and the gate region 105B. A channel layer may be provided as part of the buffer layer 104—e.g., a top portion of the buffer layer 104 proximate to a barrier layer 110. Whereas a channel layer may primarily include GaN material, there may be optional trace amounts of other group-III elements, such as aluminum or indium, in some examples.

A barrier layer 110 including III-N semiconductor material is formed over the buffer layer 104. In one example, the barrier layer 110 may have a thickness ranging from about 1 nanometer (nm) to about 60 nm, and may include aluminum and nitrogen. In some versions of this example, the barrier layer 110 may include gallium at a lower atomic percent than aluminum. In some versions, the barrier layer 110 may also include indium. In some examples, the barrier layer 110 includes an AlGaN layer.

The barrier layer 110 over the buffer layer 104 is operable as part of a heterojunction structure 106 for causing the formation of a 2DEG 108 proximate to an interface between the barrier layer 110 and the buffer layer 104. In some examples, the stoichiometry and thickness of the barrier layer 110 may be configured to provide a suitable free charge carrier density (e.g., 3×10¹² cm⁻² to 2×10¹³ cm⁻²) of the 2DEG for facilitating the device operation.

For purposes of effectuating e-mode functionality, a p-doped III-N layer 114, e.g., including one or more layers of III-N material, is formed over the barrier layer 110 as shown in FIG. 1A. In some examples, the p-doped III-N layer 114 may also be referred to as a p-III-N layer or a p-GaN layer. The formation of the p-GaN layer 114 causes the 2DEG to be reduced—e.g., absent in some cases. In some examples, the p-doped III-N layer 114 may include a GaN layer doped with magnesium (Mg) or other p-type dopants. In some examples, the p-GaN layer 114 may include a p-dopant concentration of about 1×10¹⁷ atoms/cm³ to 1×10²¹ atoms/cm³ and may have a thickness of about 10 nm to 200 nm. In some additional and/or alternative examples, additional layers such as an AlGaN cap layer (e.g., devoid of p-doping, and not specifically shown in the figures) may be provided over the p-GaN layer 114.

FIG. 1B depicts a next intermediate stage after patterning the p-GaN layer 114 using a mask and appropriate photolithography and etch process to form a part of a gate stack (structure) 112, which may include additional capping layers (e.g., AlGaN layers) in some examples in addition to a gate electrode to be subsequently formed over the p-GaN layer 114 (and the additional capping layers if present). As a result of patterning the p-GaN layer 114 (e.g., removing portions of the p-GaN layer 114 outside the gate region 105B), the 2DEG 108 is established in the channel layer outside the gate region 105B.

In some examples, the source region 105A (wherein a source contact is to be formed) and the drain region 105D (wherein a drain contact is to be formed) may be asymmetrically disposed relative to the gate region 105B although it is not a requirement. For example, there may be a greater lateral distance between the gate region 105B and the drain region 105D than a lateral distance (e.g., along the x-axis) between the gate region 105B and the source region 105A by virtue of an access region, e.g., drain access region 105C, disposed between the gate region 105B and the drain region 105D. In some additional and/or alternative examples, a source access region may also be provided between the source region 105A and the gate region 105B in a similar manner, as previously noted, while still having source/drain region asymmetry with respect to the gate region 105B.

Although not specifically shown in FIG. 1A or FIG. 1B, a suitable device isolation step may be implemented to achieve isolation with respect to the GaN device 100. Depending on implementation, an isolation step may include mesa etching, implanting, etc., to define a region where the 2DEG 108 outside the active area is absent, eliminated or otherwise disrupted. In some examples, an Ar+ implant at 120 keV having a dosage around 5×10¹⁴ atoms/cm² may be implemented to achieve device isolation.

FIG. 1C depicts a next intermediate stage wherein a dielectric layer 116 is formed over the GaN device 100, where the dielectric layer 116 extends over the p-GaN layer 114 in the gate region 105B as well as across the barrier layer 110 in the source region 105A, the drain access region 105C and the drain region 105D. In some examples, the dielectric layer 116 includes a silicon nitride (SiN) layer having a thickness of about of about 10 nm to 100 nm and may be operable to protect the p-GaN layer 114 (as well as the barrier layer 110) during the subsequent process stages. In one example, the dielectric layer 116 may be formed by a high temperature low pressure chemical vapor deposition (LPCVD) process, e.g., at temperatures ranging from about 700° C. to about 850° C., using suitable precursors such as dichlorosilane (DCS) and ammonia (NH₃). Although the dielectric layer 116 is illustrated as a single layer in FIG. 1C, it is not a requirement. Accordingly, the dielectric layer 116 may include multiple SiN layers. In some other examples, the dielectric layer 116 may include different materials, e.g., silicon dioxide (SiO₂), silicon oxynitride (SiON), aluminum oxide (Al₂O₃), etc., and may be formed using other techniques such as, for example, atomic layer deposition (ALD).

FIGS. 1D-1F depict next intermediate stages wherein, for a “gate first” process flow, a gate electrode is formed in the gate region 105B prior to forming source and drain contacts. More particularly, a gate electrode aperture 131 is formed over the p-GaN layer 114 in the gate region 105B as depicted in FIG. 1D. In some examples, a gate electrode photolithography and etch process may be performed to form the gate electrode aperture 131 in the dielectric layer 116 that exposes the p-GaN layer 114. As then shown in FIG. 1E, a conductive layer 199 is formed over the patterned dielectric layer 116 for facilitating the formation of a gate electrode. In some examples, the conductive layer 199 may include a metal layer—e.g., formed by sputtering. Depending on implementation, the conductive layer 199 may include one or more metals, such as titanium (T), nickel (Ni), tungsten (W), platinum (Pt), iridium (Ir), aluminum (Al), gold (Au), etc., and/or may include other electrically conductive materials such as carbon nanotubes or graphene as well as metallic nitrides such as titanium nitride (TiN), tantalum nitride (TaN) and the like. As then shown in FIG. 1F, a gate electrode 122 is patterned from the conductive layer 199 based on a suitable gate lithography and etch process.

FIG. 1G depicts a next intermediate stage wherein a composite dielectric layer including a dielectric layer 134 and a dielectric layer 135 are formed over gate electrode 122 and exposed surfaces of dielectric layer 116. First, in some examples, dielectric layer 134 includes a SiO₂ material, and can be deposited using suitable deposition techniques such as a plasma enhanced CVD (PECVD) process which may be performed at temperatures of around 350° C. to 400° C. that are lower than the temperatures of LPCVD used for forming dielectric layer 116. Other deposition techniques may include ALD, thermal oxidation, and the like. Depending on implementation, the dielectric layer 134 may have a thickness (e.g., along the z-axis) ranging from tens of nanometers to several hundreds of nanometers. Other dielectric materials can be used for the dielectric layer 134 including, for example, SiON, TEOS, etc. The dielectric material for dielectric layer 134 is selected to have a relatively low hydrogen content given its proximity to p-GaN layer 114 in the gate region 105B.

Recall, as described above, a dielectric material with relatively high hydrogen content (e.g., SiN) can cause p-GaN layer deactivation when H atoms from the high hydrogen content dielectric material diffuse into the p-GaN layer and deplete (or deactivate) the dopants therein. However, also recall that dielectric material with a relatively low hydrogen content may also have a relatively low dielectric constant. Thus, while SiO₂ has a relatively low hydrogen content such that p-GaN deactivation is less likely to occur, SiO₂ has a relatively low dielectric constant (κ equal to around 4). As described above, a relatively low dielectric constant in the dielectric layer 134 can cause a degradation in the TDDB lifetime of the GaN device 100 due to an increase in the magnitude of the electric field present in the dielectric layer 134, particularly at an edge of a field plate (e.g., a field plate (FP) structure 136 described below in the context of FIG. 1H) formed immediately there above.

Accordingly, as further shown in FIG. 1G, a dielectric layer 135 is formed over the dielectric layer 134 with a dielectric material having a relatively high dielectric constant (however, albeit, with a relatively high hydrogen content) so as to mitigate the above-described electric field at the edge of a field plate formed immediately above dielectric layer 135. In some examples, dielectric layer 135 includes a SiN material, and can be deposited using suitable deposition techniques such as ALD, physical vapor deposition (PVD), and the like. The dielectric layer 135 may have a thickness (e.g., along the z-axis) ranging from ones to tens of nanometers and, otherwise, a lesser thickness relative to the dielectric layer 134. Dielectric layer 135 may be formed from one or more other relatively high dielectric constant materials such as aluminum oxide (Al₂O₃), aluminum nitride (AlN), hafnium oxide (HfO₂), or any other suitable dielectric material having κ, for example, equal to or greater than 7.

In some other examples, the dielectric layer 135 may have a thickness of about 2 nm to 20 nm and may include a combination of both Al₂O₃ and AlN. For example, an AlN layer may be deposited using ALD at a temperature ranging from about 250° C. to about 350° C. with ammonia (NH₃) and trimethylaluminum (TMA) as precursors. In some examples, an Al₂O₃ layer may be deposited using ALD at similar temperatures, e.g., ranging from range of about 250° C. to about 350° C., using ozone (O₃) or water (H₂O) in combination with trimethylaluminum (TMA) as precursors.

Accordingly, the dielectric layers 134 and 135 can collectively be referred to as a “first composite dielectric layer” which provides both electric field relief functionalities (e.g., via dielectric layer 135 as a “first dielectric layer” relative to the first composite dielectric layer) and p-GaN layer deactivation mitigation functionalities (e.g., via dielectric layer 134 as a “second dielectric layer” relative to the first composite dielectric layer). Moreover, each of dielectric layers 134 and 135 may provide other functionalities with respect to GaN device 100.

As illustrated in FIG. 1H, a source field plate (FP) structure 136, which may also be referred to as a first FP structure in some examples, may be formed over the dielectric layer 135 in the source region 105A and the gate region 105B, and at least partially extending over a portion of the drain access region 105C and terminating at an edge 151. Depending on implementation, the first FP structure 136 may have a variable thickness and comprise suitable conductive materials (e.g., metals).

FIG. 1I depicts a next intermediate stage wherein another (second) composite dielectric layer including a dielectric layer 138 and a dielectric layer 139 is formed over a portion of first FP structure 136 and an exposed surface of dielectric layer 135 (or over a portion of dielectric layer 134 in alternative examples wherein dielectric layer 135 does not extend past edge 151 of the first FP structure 136). In some examples, dielectric layer 138 and dielectric layer 139 may be respectively formed similar to dielectric layer 134 and dielectric layer 135 (e.g., the first composite dielectric layer first formed in accordance with FIG. 1G).

Accordingly, in some examples, dielectric layer 138 includes a SiO₂ material, and can be deposited using a similar deposition technique as dielectric layer 134 and may have a thickness (e.g., along the z-axis) ranging from tens of nanometers to several hundreds of nanometers. In some examples, dielectric layer 138 may have a different thickness (e.g., in some examples, thicker) than dielectric layer 134. Other dielectric materials can be used for the dielectric layer 138 including, for example, SiON, TEOS, etc. Similar to dielectric layer 134, and for reasons described above, the dielectric material for dielectric layer 138 is selected to have a relatively low hydrogen content.

Likewise, in some examples, dielectric layer 139 is formed over the dielectric layer 138 with a dielectric material having a relatively high dielectric constant (however, albeit, with a relatively high hydrogen content) so as to mitigate an electric field at the edge of a field plate (e.g., a second FP structure 140 as will be described below in the context of FIG. 1J) formed immediately above dielectric layer 139. In some examples, dielectric layer 139 includes a SiN material, and can be deposited using suitable deposition techniques similar to those usable for dielectric layer 135. The dielectric layer 139 may have a thickness (e.g., along the z-axis) ranging from ones to tens of nanometers and, otherwise, a lesser thickness relative to the dielectric layer 138. In some examples, dielectric layer 139 may have a different thickness than dielectric layer 135. Also, similar to dielectric layer 135, dielectric layer 139 may be formed from one or more other relatively high dielectric constant materials such as aluminum oxide (Al₂O₃), aluminum nitride (AlN), hafnium oxide (HfO₂), or any other suitable dielectric material having κ equal to or greater than 7.

Accordingly, the dielectric layers 138 and 139 can collectively be referred to as a “second composite dielectric layer” which provides both electric field relief functionalities (e.g., via dielectric layer 139 as a “first dielectric layer” relative to the second composite dielectric layer) and p-GaN layer deactivation mitigation functionalities (e.g., via dielectric layer 138 as a “second dielectric layer” relative to the second composite dielectric layer). Moreover, each of dielectric layers 138 and 139 may provide other functionalities with respect to GaN device 100.

As illustrated in FIG. 1J, a source field plate (FP) structure 140, which may also be referred to as a second FP structure in some examples, may be formed over portions of the first FP structure 136 and dielectric layer 139, and at least partially extending over a portion of the drain access region 105C and terminating at an edge 152. Edge 152 may laterally extend (e.g., x-axis) closer to drain region 105D relative to edge 151 of the first FP structure 136. Depending on implementation, the second FP structure 140 may have a variable thickness and comprise suitable conductive materials (e.g., metals), similar to first FP structure 136.

FIG. 1J further depicts a more completely formed GaN device 100 wherein source and drain contacts 142 and 144 are respectively formed in the source and drain regions 105A and 105D using a contact mask and an etch process comprising wet etch and/or dry etch, followed by suitable metallization and annealing. Accordingly, the buffer layer 104 in the source region 105A and the drain region 105D may be exposed in respective apertures (not specifically shown in FIG. 1J) formed through respective source-side and drain-side stacks including one or more FP structures (extending to the source region), various dielectric layers, and the like. Thereafter, the contact apertures may be metallized using one or more metals such as Ti, Ni, W, Pt, Ir, Al, Au, etc., as well as metallic nitrides such as TiN, TaN, and the like. Further, a source terminal 146, a gate terminal (not expressly shown in FIG. 1J), and a drain terminal 148 may be formed through an inter-level dielectric (ILD) and/or pre-metal dielectric (PMD) insulator layer (not expressly shown in FIG. 1J) for facilitating electrical contact with source contact 142, gate electrode 122, and drain contact 144, respectively.

While GaN device 100 in FIG. 1J depicts two FP structures (e.g., first FP structure 136 and second FP structure 140) with composite dielectric layers (e.g., first composite dielectric layer including dielectric layers 134 and 135, and second composite dielectric layer including dielectric layers 138 and 139) respectively formed there-under, in some other examples, GaN device 100 may have only one FP structure and thus only one composite dielectric layer. In some examples, GaN device 100 may have more than two FP structures, such as three (3) or four (4), or even more. Although GaN device 100 in FIG. 1J depicts two FP structures (e.g., first FP structure 136 and second FP structure 140) connected to the source contact 142, the present disclosure is not limited thereto. For example, the FP structure(s) may not be connected to the source contact.

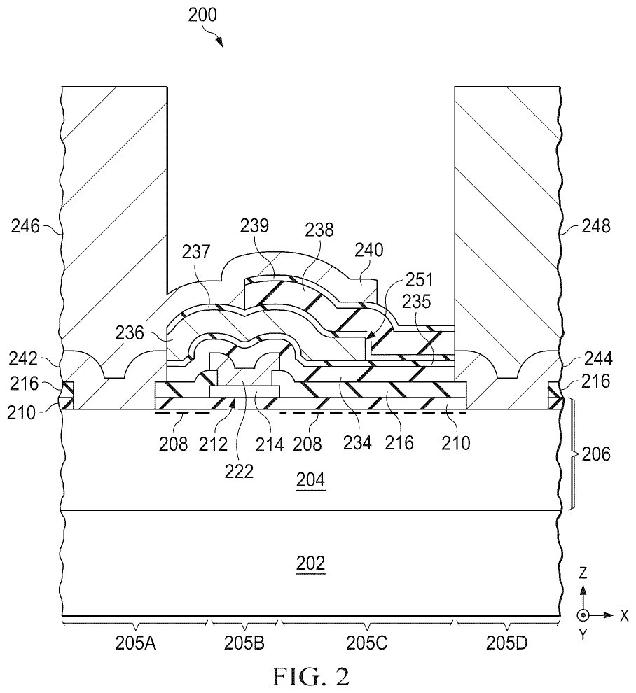

Referring now to FIG. 2, a cross-sectional view of an e-mode type GaN device 200 is shown with composite dielectric layers under field plates in accordance with another example of the present disclosure. GaN device 200 can be formed substantially identically to GaN device 100, as per FIGS. 1A-1J, and thus similar elements in FIG. 2 with reference numerals in the 200s directly correspond to similar elements in FIG. 1 with reference numerals in the 100s. An exception in GaN device 200 compared to GaN device 100 is an additional dielectric layer 237 formed, in this example, on the first FP structure 236 and connecting with dielectric layer 235 at edge 251. The additional dielectric layer 237 can be formed using suitable deposition and patterning processes following the formation of first FP structure 236. In some examples dielectric layer 237 may include the same dielectric material as dielectric layer 235 (e.g., SiN or the like).

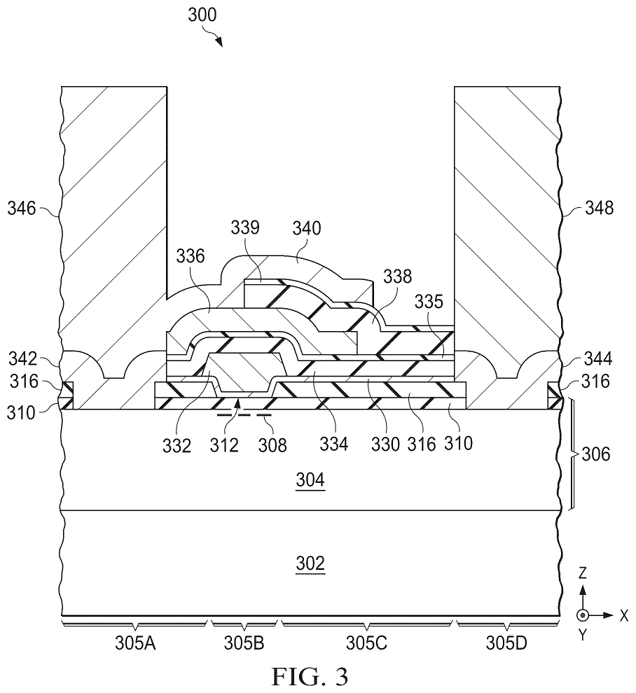

Referring to FIG. 3, a cross-sectional view of a d-mode type GaN device 300 is shown with composite dielectric layers under field plates in accordance with an example of the present disclosure. GaN device 300 can be formed substantially identically to GaN device 100, as per FIGS. 1A-1J, and thus similar elements in FIG. 3 with reference numerals in the 300s directly correspond to similar elements in FIG. 1 with reference numerals in the 100s. An exception in GaN device 300 as compared to GaN device 100 is the formation of a d-mode type gate structure rather than an e-mode type gate structure.

As shown in FIG. 3, after the formation of dielectric layer 316, a gate dielectric layer 330 and a gate electrode 332 are formed. In some examples, prior to forming the gate electrode 332, the gate dielectric layer 330 is formed on dielectric layer 316. In some examples, a mask can be used to pattern the dielectric layer 316 which is then etched to form a gate trench (not expressly shown as a separate process step) including opposing sidewalls and a bottom that exposes a portion of the barrier layer 310. Etching may include any suitable etch process, e.g., a reactive ion etch (RIE). The gate dielectric layer 330 is then deposited over the dielectric layer 316, over the sidewalls of the gate trench, and over the exposed portion of the barrier layer 310. The gate electrode 332 is then formed with a first portion of the gate electrode 332 inside the gate trench and a second portion of the gate electrode 332 outside the gate trench overlapping the gate dielectric layer 330 on opposing sides. Other suitable processes for forming a d-mode type gate structure can be used in other examples. The materials of the gate dielectric layer 330 may include, in some examples, an oxide-based dielectric such as aluminum oxide (Al₂O₃), hafnium oxide (HfO₂), and the like, although nitride-base dielectrics can also be used in other examples. The gate electrode 332 may include materials such as one or more metals, e.g., Ti, Ni, W, Pt, Ir, Al, Au, etc., as well as metallic nitrides such as TiN, TaN, and the like.

Recall that for a d-mode type GaN device, the 2DEG is present under the gate structure (as depicted by 2DEG 310 in FIG. 3) resulting in a normally-ON device which can then be turned OFF by applying a negative voltage to the gate electrode 332.

Following formation of the gate electrode 332, the first composite dielectric layer including dielectric layers 334 and 335 is formed similar to dielectric layers 134 and 135 described above, and so on to fabricate GaN device 300.

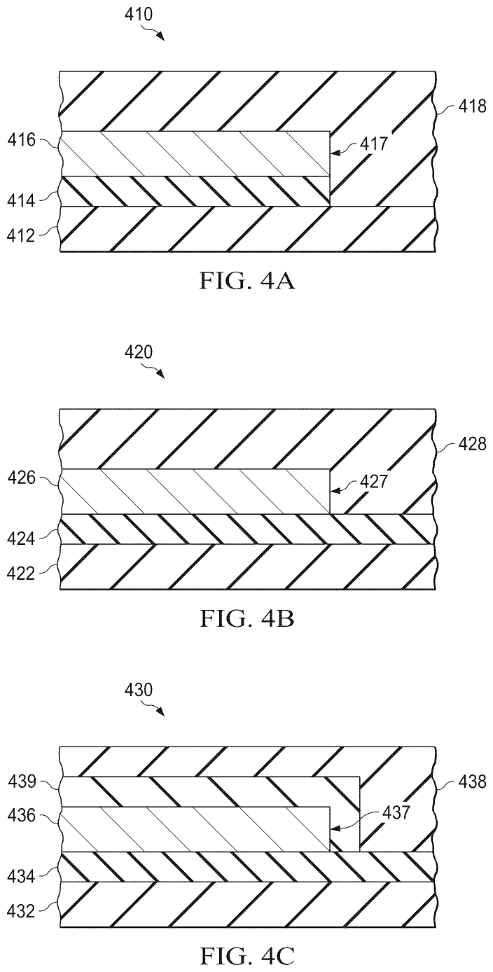

Referring now to FIGS. 4A through 4C, respective cross-sectional views of portions of semiconductor devices with composite dielectric layers under a field plate are shown in accordance with other examples of the present disclosure. The semiconductor devices partially shown in FIGS. 4A through 4C can include e-mode GaN devices, d-mode GaN devices, as well as other types of semiconductor devices.

More particularly, FIG. 4A shows a portion of a semiconductor device 410 including a dielectric layer 412 disposed above other semiconductor device elements (not expressly shown but, in some examples, a gate structure and a heterojunction structure consistent with the GaN devices shown in FIGS. 1A through 1J, FIG. 2, and/or FIG. 3 described above). Dielectric layer 412, in some examples, includes a relatively low hydrogen/low dielectric constant material such as SiO₂ SiON, TEOS, or the like. A dielectric layer 414 is disposed between a portion of dielectric layer 412 and a metallic field plate 416. Dielectric layer 414, in some examples, includes a relatively high dielectric constant material such as SiN, Al₂O₃, AlN, HfO₂, or the like. Dielectric layers 412 and 414 collectively form a composite dielectric layer, under metallic field plate 416, that is operative to provide advantages described herein including, for example, both electric field relief functionalities (e.g., via dielectric layer 414) and p-GaN layer deactivation mitigation functionalities (e.g., via dielectric layer 412).

In the FIG. 4A example, the relatively high dielectric constant layer 414 is patterned in conjunction with metallic field plate 416 when formed. As a result, dielectric layer 414 terminates at an edge 417 of metallic field plate 416. As further shown, a dielectric layer 418 is disposed above metallic field plate 416 and can include a relatively low hydrogen/low dielectric constant material such as SiO₂ SiON, TEOS, and the like, similar to dielectric layer 412. In the FIG. 4A example, dielectric layer 412 and 418 connect as shown.

FIG. 4B shows a portion of a semiconductor device 420 which is a variation of the portion of the semiconductor device 410 in FIG. 4A. Thus, elements 422, 424, 426, 427, and 428 in FIG. 4B respectively correspond to elements 412, 414, 416, 417, and 418 in FIG. 4A. However, in the FIG. 4B example, metallic field plate 426 is patterned on its own and, as a result, dielectric layer 424 extends beyond edge 427 of metallic field plate 426, and dielectric layers 422 and 428 do not connect.

Lastly, FIG. 4C shows a portion of a semiconductor device 430 which is a variation of the portion of the semiconductor device 420 in FIG. 4B. Thus, elements 432, 434, 436, 437, and 438 in FIG. 4C respectively correspond to elements 422, 424, 426, 427, and 428 in FIG. 4B. However, in the FIG. 4C example, an additional dielectric layer 439 is disposed under dielectric layer 438 and on metallic field plate 436. Dielectric layer 439 may be a material having the same or similar dielectric constant as dielectric layer 434, e.g., a material such as SiN, Al₂O₃, AlN, HfO₂, or the like. As a result, dielectric layer 439 has a dielectric constant greater than dielectric layers 432 and 438. Still further, in the FIG. 3C example, dielectric layer 439 connects with dielectric layer 434 at edge 437 of metallic field plate 436.

In some other examples, the semiconductor devices partially shown in FIGS. 4A through 4C may have more than one metallic field plate, such as two (2), three (3), four (4), or even more, with similar composite dielectric layers disposed there-under.

Although foregoing descriptions and examples of forming one or more composite dielectric layers are set forth in conjunction with a metallic field plate, the present disclosure is not limited thereto. For example, composite dielectric layers may be formed around one or more terminating edges of a gate electrode (e.g., gate electrodes 122, 222, 332). In that manner, the composite dielectric layers may mitigate the electric field issue at the edge(s) of a gate electrode. FIGS. 4A, 4B, and 4C may be modified to illustrate such configurations with composite dielectric layers formed in conjunction with a gate electrode. Namely, respective metallic field plates 416, 426, 436 depicted in FIGS. 4A, 4B, and 4C may be replaced with a gate electrode. As such, at least a portion of the gate electrode (e.g., terminating portions) may be disposed on a composite dielectric layer including a first dielectric layer (e.g., dielectric layer 414) formed on a second dielectric layer (e.g., dielectric layer 412).

In some examples, the first dielectric layer (e.g., dielectric layer 414 over dielectric layer 412) may terminate at the edge of the gate electrode. In other examples, the first dielectric layer (dielectric layer 414 over dielectric layer 412) may extend beyond the edge of the gate electrode. In some examples, the semiconductor device may include a third dielectric layer (e.g., dielectric layer 439) disposed on the gate electrode, where the third dielectric layer may have a third dielectric constant greater than the second dielectric layer. Still further, in some examples, the third dielectric layer may connect with the first dielectric layer at the edge of the gate electrode.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor substrate including a source region, a gate region, a drain region, and a drain access region between the gate region and the drain region;
a heterojunction structure disposed over the semiconductor substrate, the heterojunction structure including a buffer layer over the semiconductor substrate and a barrier layer over the buffer layer;
a field plate disposed over the heterojunction structure and including an edge terminated over the drain access region; and
a composite dielectric layer disposed below the field plate, wherein the composite dielectric layer comprises a first dielectric layer having a first dielectric constant and a second dielectric layer having a second dielectric constant different than the first dielectric constant.

2. The semiconductor device of claim 1, wherein the first dielectric layer is disposed between the field plate and the second dielectric layer, the first dielectric layer having a greater dielectric constant than the second dielectric layer.

3. The semiconductor device of claim 1, wherein the first dielectric layer includes a silicon nitride-based material or a transition metal oxide-based material, and the second dielectric layer includes a silicon oxide-based material.

4. The semiconductor device of claim 1, wherein the first dielectric layer has a first thickness, and the second dielectric layer has a second thickness greater than the first thickness.

5. The semiconductor device of claim 1, wherein the first dielectric layer terminates at the edge of the field plate.

6. The semiconductor device of claim 1, wherein the first dielectric layer extends beyond the edge of the field plate.

7. The semiconductor device of claim 1, further comprising a third dielectric layer disposed on the field plate.

8. The semiconductor device of claim 7, wherein the third dielectric layer has a third dielectric constant greater than the second dielectric layer.

9. The semiconductor device of claim 7, wherein the third dielectric layer connects with the first dielectric layer at the edge of the field plate.

10. The semiconductor device of claim 1, wherein the field plate is a first field plate of a set of field plates disposed over the heterojunction structure, the first field plate being the closest to the heterojunction structure.

11. The semiconductor device of claim 1, further comprising:
a set of composite dielectric layers;
wherein the composite dielectric layer is a first one of the set of composite dielectric layers and disposed below the field plate; and
wherein a second one of the set of composite dielectric layers is disposed above the field plate, the second one of the set of composite dielectric layers comprising a first dielectric layer having the first dielectric constant and a second dielectric layer having the second dielectric constant.

12. The semiconductor device of claim 1, wherein the gate region comprises:
a p-doped gallium nitride (GaN) layer disposed on the barrier layer of the heterojunction structure; and
a gate electrode disposed on the p-doped GaN layer.

13. The semiconductor device of claim 1, wherein the gate region comprises:
a gate dielectric layer disposed over the barrier layer of the heterojunction structure;
and a gate electrode partially disposed in the gate dielectric layer and disposed above the barrier layer.

14. A semiconductor device, comprising:
a gallium nitride (GaN) heterojunction structure disposed over a substrate, the GaN heterojunction structure including a barrier layer disposed on a GaN layer;
a source contact;
a drain contact;
a gate structure disposed over the GaN heterojunction structure and between the source contact and the drain contact, and the gate structure comprising:
a p-doped GaN layer disposed on the barrier layer of the GaN heterojunction structure; and
a gate electrode disposed on the p-doped GaN layer;
a set of field plates disposed over the gate structure and extending from the source contact toward the drain contact; and
a set of composite dielectric layers, a first one of the set of composite dielectric layers being disposed below a first one of the set of field plates, a second one of the set of composite dielectric layers being disposed below a second one of the set of field plates, wherein each of the set of composite dielectric layers comprises a first dielectric layer having a first dielectric constant and a second dielectric layer having a second dielectric constant different than the first dielectric constant.

15. The semiconductor device of claim 14, wherein the first dielectric layer of each of the set of composite dielectric layers is disposed between the corresponding field plate and the second dielectric layer, the first dielectric layer having a greater dielectric constant than the second dielectric layer.

16. The semiconductor device of claim 14, wherein the first dielectric layer of each of the set of composite dielectric layers has a hydrogen content greater than the second dielectric layer.

17. The semiconductor device of claim 14, wherein the first dielectric layer of each of the set of composite dielectric layers includes a silicon nitride-based material or a transition metal oxide-based material, and the second dielectric layer includes a silicon oxide-based material.

18. The semiconductor device of claim 14, further comprising a third dielectric layer disposed on the lower one of the set of field plates and having the same dielectric constant as the first dielectric layer of each of the set of composite dielectric layers.

19. The semiconductor device of claim 18, wherein the third dielectric layer connects with the first dielectric layer of the composite dielectric layer corresponding to the lower one of the set of field plates.

20. A method of fabricating a semiconductor device, comprising:
forming a semiconductor substrate including a source region, a gate region, a drain region, and a drain access region between the gate region and the drain region;
forming a heterojunction structure over the semiconductor substrate, the heterojunction structure including a buffer layer over the semiconductor substrate and a barrier layer over the buffer layer;
forming a composite dielectric layer over the heterojunction structure, wherein the composite dielectric layer comprises a first dielectric layer having a first dielectric constant and a second dielectric layer having a second dielectric constant different than the first dielectric constant; and
forming a field plate over the composite dielectric layer and including an edge terminated over the drain access region.

21. The method of claim 20, wherein the first dielectric layer is formed between the field plate and the second dielectric layer, the first dielectric layer having a greater dielectric constant than the second dielectric layer, and the first dielectric layer having a first thickness and the second dielectric layer having a second thickness greater than the first thickness.

22. The method of claim 20, further comprising:
forming a third dielectric layer on the field plate, wherein the third dielectric layer has a third dielectric constant greater than the second dielectric layer.

23. The method of claim 20, further comprising:
forming a set of composite dielectric layers;
wherein the composite dielectric layer is a first one of the set of composite dielectric layers and formed below the field plate; and
wherein a second one of the set of composite dielectric layers is formed above the field plate, the second one of the set of composite dielectric layers comprising a first dielectric layer having the first dielectric constant and a second dielectric layer having the second dielectric constant.

24. The method of claim 20, wherein forming the semiconductor substrate further comprises:
forming the gate region to include a p-doped GaN layer on the barrier layer of the heterojunction structure, and a gate electrode on the p-doped GaN layer.

25. The method of claim 20, wherein forming the semiconductor substrate further comprises:
forming the gate region to include a gate dielectric layer over the barrier layer of the heterojunction structure, and a gate electrode partially in the gate dielectric layer and above the barrier layer.
